(19) United States
(12) Patent Application Publication
(10) Pub. No.: US 2004/0144984 A1
(43) Pub. Date: Jul. 29, 2004

(54) Fabrication method for surface emitting semiconductor device and surface emitting semiconductor device

(75) Inventors: Andrea Knigge, Wildau (DE); Martin Zorn, Berlin (DE); Markus Weyers, Wildau (DE); Hans Wenzel, Berlin (DE)

Correspondence Address: MILLEN, WHITE, ZELANO & BRANIGAN, P.C., 2200 CLARENDON BLVD., SUITE 1400, ARLINGTON, VA, 22201, US

(73) Assignee: Forschungsverbund Berling e.V., Berlin (DE)

(21) Appl. No.: 10/353,092

(22) Filed: Jan. 29, 2003

(51) Int. Cl. H01L 27/15

(52) U.S. Cl. 257/79

(57) ABSTRACT

A method or fabricating a surface emitting semiconductor device like a GaAs-based vertical cavity surface emitting laser diode comprising basically a substrate, two stacks of Bragg mirrors surrounding a laser cavity containing the active region and a contact layer on top of the DBR facing the light extraction window 13 featuring a layer (2) made form gallium-indium-phosphide (GaInP) epitaxially deposited during the growth of the layer sequence.

The invention is a fabrication method for a surface emitting semiconductor device according to the definition of claims 1 to 6 and a surface emitting semiconductor device according to the definition of claims 7 and 12.

A vertical cavity surface emitting laser (VCSEL) basically consists of two stacks of semiconductor Bragg mirrors (DBR; distributed Bragg reflector) surrounding a laser cavity that contains the active light emitting region. The semiconductor DBRs consist of layers with different compositions of AlₓGa₁₋ₓAs which are designed that way that the optical path in each of the layers is one quarter of the desired emission wavelength of the device. (J. Jewell et al.: “Vertical-cavity surface-emitting lasers: design, growth, fabrication, charactrization, IEEE Journal of Quantum Electronics”, Vol. 27, No. 6. June 1991, p. 1332-1346; W. W. Chow et al.: “Design, Fabrication, and Performance of infrared and visible vertical-cavity surface-emitting lasers”, IEEE Journal of Quantum Electronics, Vol. 33, No. 10. October 1997, p. 1810-1823).

To obtain good electrical (ohmic) contact usually the top DBR stack is capped with a highly doped contact layer made from gallium arsenide (GaAs) which is grown in the final step of the epitaxial growth of the whole layer structure. This contact layer allows for the formation of an ohmic contact with a low contact resistivity to the metal layer deposited in subsequent process steps.

Usually, the upper DBR mirror is p-doped and so the contact layer consists of p⁺⁺-GaAs with doping levels of some 10¹⁹ cm⁻³. Typically, such contact layers have thicknesses of 50-300 nm. For a good contact layer thicknesses of above 100 nm are preferred.

Unfortunately, GaAs, especially highly p-doped GaAs, absorbs light with photon energies Eₚₕₒₜₒₙ above the band gap energy E_{gap} (GaAs) of 1.4 eV.

For an efficient operation of a VCSEL device, especially at wavelengths shorter than 850 nm, a removal of the absorbing contact layer in the window area where the light is extracted from the semiconductor is highly desirable. In a device representing the present state of the art this would expose the topmost AlₓGa₁₋ₓAs (1≦x>0) layer of the DBR. AlₓGa₁₋ₓAs surfaces, especially those containing a high fraction of Al, are known to oxidize when exposed to air.

The forming oxide is not stable and can even peel of for high Al concentrations. This results in unstable device performance. The oxidation process can even be enhanced when light from the device is absorbed by the interface region between the partially oxidized semiconductor and air.

Additionally, surface states forming on the AlGaAs layer exposed to air may lead to nonradiative recombination. Charge carriers lost in such processes contribute to the heating of the device without adding to the light output.

An AlGaAs surface exposed to air thus results in reduced efficiency and a limited operation lifetime of the device.

The use of a protective coating on the emission window of a VCSPL device is described in the German patent DE 199 45 128 A 1. This patent relates to a (dielectric) protective coating deposited after removing the contact layer in the course of the device fabrication process, This implies that the topmost AlGaAs layer of the DBR is at least temporarily exposed to atmosphere resulting in oxidation. The protective layer deposited subsequently can not prevent oxidation that has already taken place before its deposition but can only prevent continuation of the oxidation process.

The use of GaInP as etch stop layer is described in DE 695 05 900 T2. This patent relates to a fabrication procedure and a device structure for edge-emitting semiconductor laser diodes in which the cladding layer is made from AlGaAs which is grown on top of a thin GaInP etch-stop layer that is inserted between the AlGaAs cladding layer and the AlGaAs waveguide layer. This layer has only the function of an etch-stop layer allowing for a selective removal of the AlGaAs cladding layer and thus a well defined etch depth. The etch-stop layer in DE 695 05 900 T2 is parallel to the propagation direction of the light and is not passed by the laser emission. This means that the requirements on absorption and also matching of the refractive index to the surrounding layers are relaxed in comparison to the present invention, Additionally, the etch-stop layer of DE 695 05 900 T2 is only exposed in the passive region of the device where no current flows. In contrast to the devices covered by the present invention, no protective function is related to this etch-stop layer.

Thus the present invention combining the protective nature of GaInP with its properties as etch-stop layer, as layer through which current is passed and through which the light emission from the device is extracted and which has to be designed that way that its optical properties are matched to that of the surrounding layers in order to ensure the device functionality exceeds the previous inventions.

The purpose of the presented invention to use a special device design and a special fabrication process in order to allow for a removal of the absorbing contact layer without exposing highly Al-containing layers to air during the whole device fabrication process.

This task is achieved by the fabrication procedure according to claims 1 to 6 and the properties of the semiconductor device according to claims 7 to 12.

The fabrication procedure entails that a layer of InGaP, which is stable against air exposure, is introduced during the epitaxial growth of the semiconductor heterostructure between the last highly Al-containing layer of the DBR and the highly doped and absorbing contact layer. This contact layer can either be deposited together with the rest of the semiconductor heterostructure and subsequently be removed by etching or it can be deposited in a patterned way by selective regrowth in a second growth step.

The InGaP layer acts as a protective layer for the underlying highly Al-containing layers during the whole device fabrication process since it is deposited before the first exposure to atmosphere and never removed. If the contact layer is deposited on the full wafer in the same growth process like the InGaP protective window layer, the GaAs contact layer can be patterned by selective etching procedures that attack GaAs but not GaInP.

If Al is added to the protective etch stop layer to form AlGaInP the functionality of this layer is the same but it can be applied for devices at even shorter wavelengths since AlGaInP has a wider bandgap than GaInP. The sensitivity to exposure to atmosphere will be increased with increasing Al mole fraction x1 in (Al₂ₓ₁Ga₁₋₂ₓ₁)_{0.5}In_{0.5}P but it is in any case lower than the sensitivity of Alₓ₂Ga₁₋ₓ₂As of the same bandgap energy since x1 is smaller than x2 Thus the etch stop and protective layer to which this invention relates can be formed from GaInP or (Al₂ₓGaₗ₋₂ₓ)_{0.5}P.

If the device is operating as a bottom emitter the protective etch stop layer is placed below the first layer of the lower AlGaAs Bragg mirror on top of the GaAs substrate or a buffer deposited between the substrate and the layer sequence forming the device. In this embodiment the GaAs substrate in the emission window is etched selectively down to the protective etch stop layer in the same fashion like the contact layer is etched in a device emitting from the top.

The fabrication process can but must not entail the deposition of a further dielectric layer on top of the etch stop layer which can be used to adjust the reflectivity and/or as a further protection effectively sealing the semiconductor against contact to the environment. Such an additional layer is for example described in DE 199 45 128 A 1.

The semiconductor device to which this invention relates has a protective layer made from GaInP which is stable against air exposure on top of the uppermost layer of the AlGaAs Bragg mirror and below the highly doped and absorbing GaAs contact layer which is either etched away in the emission window or is deposited in a selective fashion only outside of the emission window.

In another embodiment the device has a protective etch stop layer made from AlGaInP which allows for shorter emission wavelengths due to its higher bandgap.

In yet another embodiment of the device the GaInP or AlGaInP protective etch stop layer is located below the bottom AlGaAs DBR in a bottom emitting device where the substrate is removed in the emission window.

Besides the application in VCSEL devices the invention can also be used for other surface emitting, devices like resonant-cavity light emitting diodes (RCLEDs). The latter device has a reduced number of layer pairs in the DBR in comparison to a VCSEL, for example only 5 pairs on the p-side and 15 pairs on the n-side. Even for devices having no DBR mirrors but AlGaAs layers on the light emission side the use of the protecting etch stop layer can be advantageous.

Embodiments of the invention are described in the claims.

The invention is explained based on 5 examples and figures. However, it is not limited to the cases illustrated in these figures. The figures show:

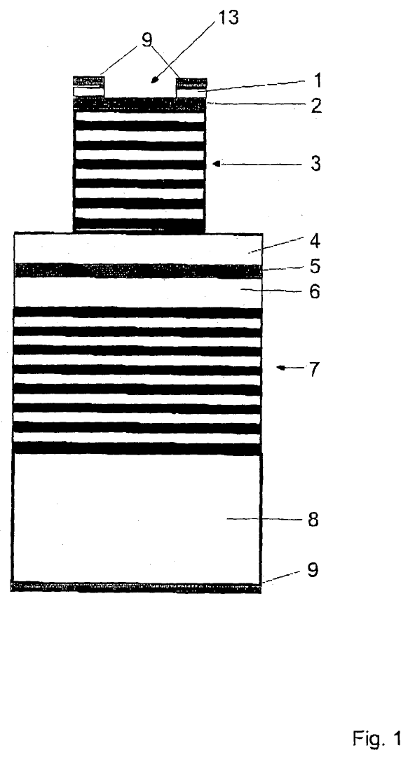

FIG. 1: Schematic of typical layer structure of a mesa-top-emitter

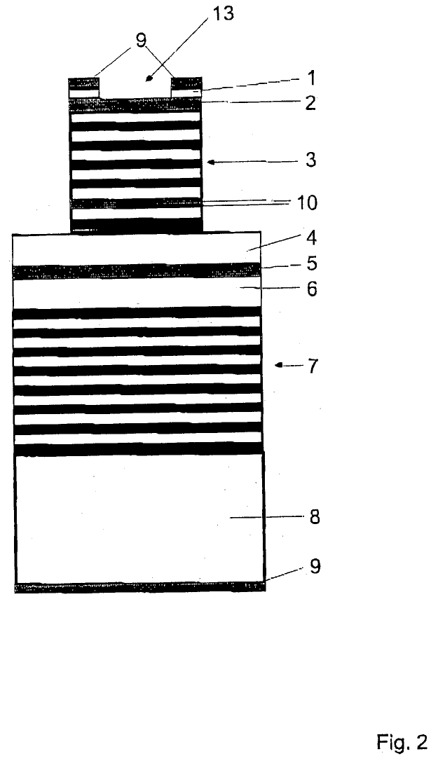

FIG. 2: Schematic of typical layer structure of a top-emitter with oxide aperture

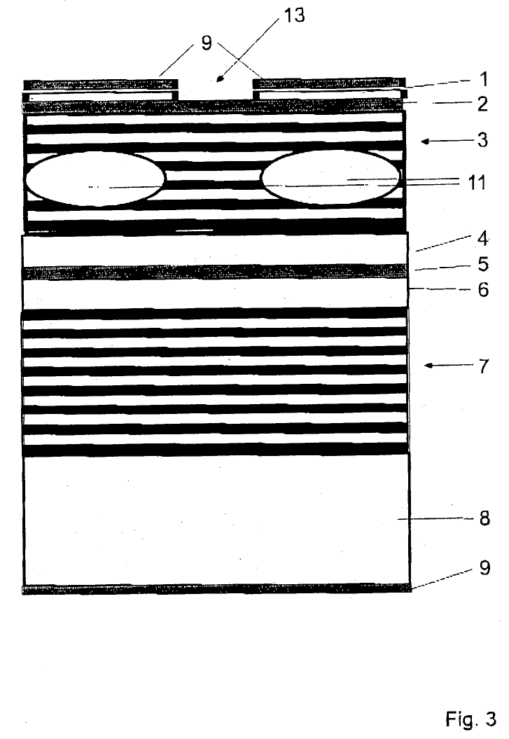

FIG. 3 Schematic of typical layer structure of a top-emitter with aperture formed by ion implantation

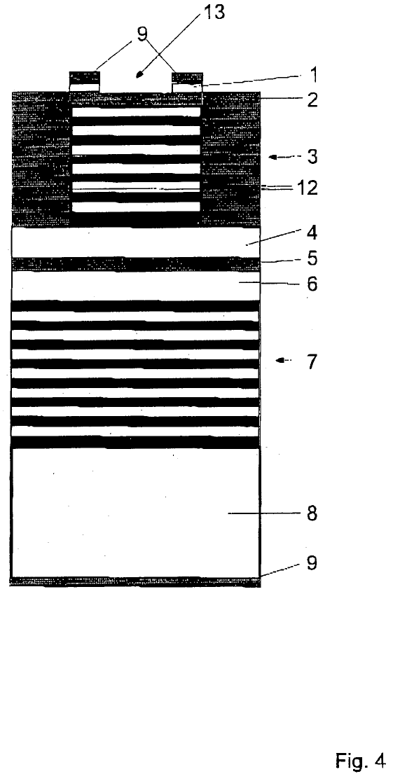

FIG. 4: Schematic of typical layer structure of a top-emitter with contact regions formed by a second selective growth step

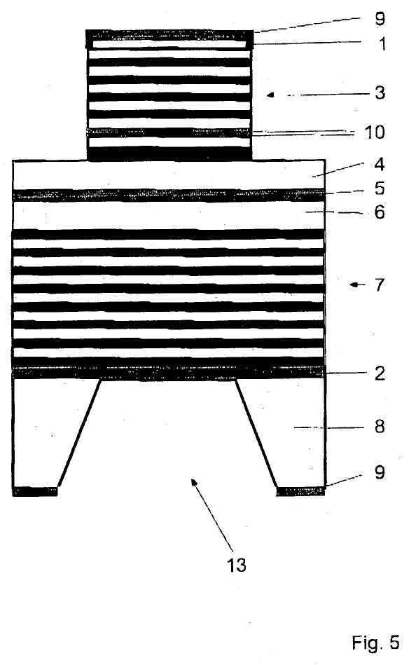

FIG. 5: Schematic of typical layer structure of a bottom-emitter according to the invention

A top-emitter according to the invention as shown in FIGS. 1-4 consists of a GaAs substrate 8, two stacks of DBR 3, 7 for example formed from AlGaAs-AlGaAs layer pairs, a cavity with two intermediate layers 4,6, in which the active region 5 in form of one or more quantum wells (QW) is embedded and the protective etch stop layer made from GaInP (or AlGaInP) on top of which the contact layer 1 and the metal contacts 9 are deposited.

FIG. 1 depicts a first embodiment of the device structure for a mesa-top-emitter with typical material compositions and layer thicknesses.

The mesa-top-emitter according to FIG. 1 consists of

1 a contact layer made from 80 nm GaAs (p=2×10¹⁹ cm⁻³)

2 a protective etch stop layer made from 10 nm GaInP (p=7×10¹⁸ cm⁻³) (alternatively this layer can be formed from AlGaInP)

3 a p-DBR stack made from λ/4 layers of Al_{0.5}Ga_{0.5}As and Al_{0.95}Ga_{0.5}As (p=3×10¹⁸ cm⁻³)

4 a p-type intermediate layer made from 80 nm AlGaInP

5 the active region with 3 GaInP QWs with AlGaInP barriers with a total thickness of 50 nm

6 an n-type intermediate layer made from 80 nm AlGaInP

7 an n-DBR stack made from λ/4 layers of Al_{0.5}Ga_{0.5}As and AlGaAs (n=1×10¹⁸ cm⁻¹)

8 an n-GaAs substrate and

9 metal contacts

13 light extraction window

The protective etch stop layer 2 is inserted between the GaAs contact layer 1 and the AlGaAs DBR stack 3. It protects the DBR layers 3 with a high Al-content from oxidation.

FIG. 2 depicts another embodiment of the present invention in form of a top-emitter with oxide aperture with typical material compositions and layer thicknesses

The top-emitter with oxide aperture according to FIG. 2 consists of

1 a contact layer made from 80 nm GaAs (p=2×10¹⁹ cm⁻³)

2 a protective etch stop layer made from 10 nm GaInP (p=7×10¹⁸ cm⁻³) (alternatively this layer can be formed from AlGaInP)

3 a p-DBR stack made from λ/4 layers of Al_{0.5}Ga_{0.5}As and Al_{0.05}Ga_{0.95}As (p=3×10¹⁸ cm⁻³)

4 a p-type intermediate layer made from 80 nm AlGaInP

5 the active region with 3 GaInP QWs with AlGaInP barriers with a total thickness of 50 nm

6 an n-type intermediate layer made from 80 nm AlGaInP

7 an n-DBR stack made from λ/4 layers of Al_{0.5}Ga_{0.5}As and AlGaAs (n=1×10¹⁸ cm⁻³)

8 an n-GaAs substrate and

9 metal contacts

10 oxide aperture made by wet oxidation

13 light extraction window

FIG. 3 shows a third embodiment of the invention, in which the current aperture is formed by ion implantation resulting in areas of high resistivity. Such a top-emitter with ion implanted region consists of

1 a contact layer made from 80 nm GaAs (p=2×10¹⁹ cm⁻³)

2 a protective etch stop layer made from 10 nm GaInP (p=7×10¹⁸ cm⁻³) (alternatively this layer can be formed from AlGaInP)

3 a p-DBR stack made from λ/4 layers of Al_{0.5}Ga_{0.5}As and Al_{0.95}Ga_{0.05}As (p=3×10¹⁸ cm⁻³)

4 a p-type intermediate layer made from 80 nm AlGaInP

5 the active region with 3 GaInP QWs with AlGaInP barriers with a total thickness of 50 nm

6 an n-type intermediate layer made from 80 nm AlGaInP

7 an n-DBR stack made from λ/4 layers of Al_{0.5}Ga_{0.5}As and AlGaAs (n=1×10¹⁸ cm⁻³)

8 an n-GaAs substrate and

9 metal contacts

11 regions made highly resistive by ion implantion

13 light extraction window

In a fourth embodiment of the present invention the GaAs contact layer 1 of the top-emitter is formed only in the regions necessary for contact formation by a second selective growth step.

The top-emitter with selectively grown contact layer is shown in FIG. 4 with typical material compositions and thicknesses:

2 a protective layer made from 10 nm GaInP (p 7×10¹⁸ cm⁻³)

3 a p-DBR stack made from λ/4 layers of Al_{0.5}Ga_{0.5}As and Al_{0.95}Ga_{0.05}As (p=3×10¹⁸ cm⁻³)

4 a p-type intermediate layer made from 80 nm AlGaInP

5 the active region with 3 GaInP QWs with AlGaInP barriers with a total thickness of 50 nm

6 an n-type intermediate layer made from 80 nm AlGaInP

7 an n-DBR stack made from λ/4 layers of Al_{0.5}Ga_{0.5}As and AlGaAs (n=1×10¹⁸ cm⁻³)

8 an n-GaAs substrate and

9 metal contacts

12 a contact layer made p-GaAs selectively deposited in a second growth step

in this embodiment the GaInP protective layer is the final layer of a first epitaxial layer sequence. It protects the underlying AlGaAs layers during processing for selective regrowth of the GaAs contact layer.

The embodiments according to FIGS. 1, 2 and 3 can also be realized as bottom emitters when the protective etch-stop layer 2 is inserted below the bottom DBR 7 on top of the GaAs substrate 8 (or a buffer layer grown between the substrate and the active device structure). Either holes are etched into the substrate 8 to form the light extraction region 13 or the complete substrate 8 is removed after the layer structure has been mounted with its top side onto a support giving mechanical stability.

FIG. 5 depicts this embodiment of the present invention in form of an oxide confined bottom-emitter with a hole for light extraction etched into the substrate with typical material compositions and layer thicknesses.

The bottom-emitter with ion implantation according to FIG. 5 consists of

1 a contact layer made from 80 nm GaAs (p=2×10¹⁹ cm⁻³)

2 a protective etch stop layer made from 10 nm GaInP (p=7×10¹⁸ cm⁻³) (alternatively this layer can be formed from AlGaInP)

3 a p-DBR stack made from λ/4 layers of Al_{0.5}Ga_{0.5}As and Al_{0.95}Ga_{0.05}As (p=3×10¹⁸ cm⁻³)

4 a p-type intermediate layer made from 80 nm AlGaInP

5 the active region with 3 GaInP QWs with AlGaInP barriers with a total thickness of 50 nm

6 an n-type intermediate layer made from 80 nm AlGaInP

7 an n-DBR stack made from λ/4 layers of Al_{0.5}Ga_{0.5}As and AlGaAs (n=1×10¹⁸ cm⁻³)

8 an n-GaAs substrate and

9 metal contacts

10 oxide aperture made by wet oxidation

13 light extraction window

Index:

1 contact layer made from GaAs

2 protective etch stop layer made from GaInP (alternatively this layer can be formed from AlGaInP)

3 p-DBR stack

4 p-type intermediate layer

5 active region

6 n-type intermediate layer

7 n-DBR stack

8 n-GaAs substrate

9 metal contacts

10 oxide aperture made by wet oxidation

11 ion implanted regions

12 area deposited in a second growth step

13 light extraction window

Without further elaboration, it is believed that one skilled in the art can, using the preceding description, utilize the present invention to its fullest extent. The following preferred specific embodiments are, therefore, to be construed as merely illustrative, and not limitative of the remainder of the disclosure in any way whatsoever.

In the foregoing and in the following examples, all temperatures are set forth uncorrected in degrees Celsius and, all parts and percentages are by weight, unless otherwise indicated.

The entire disclosure[s] of all applications, patents and publications, cited herein are incorporated by reference herein.

The preceding examples can be repeated with similar success by substituting the generically or specifically described reactants and/or operating conditions of this invention for those used in the preceding examples.

From the foregoing description, one skilled in the art can easily ascertain the essential characteristics of this invention and, without departing from the spirit and scope thereof, can make various changes and modifications of the invention to adapt it to various usages and conditions.

1. Method of fabricating a surface emitting semiconductor device like GaAs-based vertical cavity surface emitting laser diode consisting of basically a substrate, two stacks of Bragg mirrors surrounding a laser cavity containing the active region and a contact layer on top of the DBR facing the light extraction window 13 featuring a layer (2) made from gallium-indium-phosphide (GaInP) epitaxially deposited during the growth of the layer sequence. This GaInP layer acts as an etch stop layer in the process of formation of the light extraction window (13) and is stable against air exposure thus protecting the Al-rich layers of the adjacent DBR (3 or 7) from oxidation.

2. Method according to claim 1 in which the protective GaInP (2) layer is placed between the top DBR (3) and the GaAs top contact layer (1).

3. Method according to claim 2 in which a first layer sequence has the protective GaInP (2) layer as final layer and in which the GaAs top contact layer is deposited in well-defined areas after initial steps of device processing.

4. Method according to claim 1 in which the protective GaInP (2) layer is placed between the bottom DBR (7) and the GaAs substrate (8) or a buffer deposited on this substrate underneath the active device structure.

5. Method according to claims 1, 2, 3 and 4 in which the GaInP layer (2) is replaced by aluminium-gallium-indium-phosphide (AlGaInP) which is less resistant against oxidation by air exposure than GaInP but is transparent to shorter wavelengths.

6. Method according to claims 1 to 5 in which the device is a resonant-cavity light emitting diode (RCLED) or a conventional LED with highly Al-containing cladding layers.

7. Light emitting device with emission perpendicular to the layer sequence consisting of basically a substrate, two stacks of Bragg mirrors surrounding a laser cavity containing the active region and a contact layer on top of the DBR facing the light extraction window 13 featuring a layer (2) made from gallium-indium-phosphide (GaInP) epitaxially deposited during the growth of the layer sequence. This GaInP layer acts as an etch stop layer in the process of formation of the light extraction window (13) and is stable against air exposure thus protecting the Al-rich layers of the adjacent DBR (3 or 7) from oxidation.

8. Light emitting device with emission perpendicular to the layer sequence according to claim 7 in which the protective GaInP (2) layer is placed between the top DBR (3) and the GaAs top contact layer (1).

9. Light emitting device with emission perpendicular to the layer sequence according to claim 7 in which a first layer sequence has the protective GaInP (2) layer as final layer and in which the GaAs top contact layer is deposited in well-defined areas after initial steps of device processing.

10. Light emitting device with emission perpendicular to the layer sequence according to claim 7 in which the protective GaInP (2) layer is placed between the bottom DBR (7) and the GaAs substrate (8) or a buffer deposited on this substrate underneath the active device structure.

11. Light emitting device according to claims 7 to 10 in which the GaInP layer (2) is replaced by aluminium-gallium-indium-phosphide (AlGaInP) which is less resistant against oxidation by air exposure than GaInP but is transparent to shorter wavelengths.

12. Light emitting device according to claims 7 to 11 in which the device is a resonant-cavity light emitting diode (RCLED) or a conventional LED with highly Al-containing cladding layers.
